(19) United States
(12) Patent Application Publication
(10) Pub. No.: US 2020/0274094 A1
(43) Pub. Date: Aug. 27, 2020

(54) DISPLAY PANEL, METHOD OF MANUFACTURING THE SAME, AND DISPLAY DEVICE

(71) Applicant: Wuhan China Star Optoelectronics Semiconductor Display Technology Co., Ltd., Wuhan (CN)

(72) Inventor: Yuan ZHENG, (US)

(73) Assignee: Wuhan China Star Optoelectronics Semiconductor Display Technology Co., Ltd., Wuhan (CN)

(21) Appl. No.: 16/488,596

(22) PCT Filed: Apr. 16, 2019
(86) PCT No.: PCT/CN2019/082795

§ 371 Date: Aug. 26, 2019

(30) Foreign Application Priority Data
Feb. 27, 2019 (CN) 201910147445.5

(51) Int. Cl. H01L 51/52; H01L 27/32; H01L 51/56

(52) U.S. Cl. CPC H01L 51/5253; H01L 51/56; H01L 27/3244

(57) ABSTRACT

A display panel, a manufacturing method thereof, and a display device are provided. The display panel includes: a substrate, the substrate including a display area and a non-display area disposed around the display area; a first barrier layer, disposed on the non-display area and disposed around an edge of the display area; a second barrier layer, disposed on the first barrier layer; wherein the second barrier layer includes at least two rings of first barrier walls, and the first barrier walls are disposed around the display area.

### FIELD OF INVENTION

The present invention relates to a field of display panel technology, and in particular to a display panel, a manufacturing method thereof, and a display device.

### BACKGROUND OF INVENTION

Active-matrix organic light emitting diodes, referred to as AMOLEDs, are active matrix organic light emitting diode panels. They have self-luminescent properties, which uses very thin organic material coatings and glass substrates, and when current passes, these organic materials glow. An AMOLED panel is self-illuminating, does not require a backlight, has a wide viewing angle and high color saturation, especially its low driving voltage and low power consumption, coupled with fast response times, light weight, thin thickness, simple structure, low cost, etc., is regarded as one of the most promising products.

At present, AMOLED display technology has become a technology that many consumers pay attention to, but the failure phenomenon of OLED devices has been bothering many researchers. OLED luminescent materials are particularly sensitive to oxygen and water vapor. Organic materials are susceptible to corrosion by oxygen and water vapor, therefore the lifetime and stability of AMOLED devices is still a key issue for AMOLED technology.

### SUMMARY OF INVENTION

The present application provides a display panel, a manufacturing method thereof, and a display device, which can more effectively block the leakage of a material of a thin film encapsulation and protect an organic material in a display area from water and oxygen, thereby improving the stability and prolonging the life.

In order to solve the above problems, an embodiment of the present application provides a display panel, and the display panel includes: a substrate including a display area and a non-display area disposed around the display area; a first barrier layer disposed on the non-display area and disposed around an edge of the display area; and a second barrier layer disposed on the first barrier layer; wherein the second barrier layer includes at least two rings of first barrier walls, and the first barrier walls are disposed around the display area.

Further, the first barrier layer includes at least one ring of second barrier wall, the second barrier wall is disposed around the edge of the display area, and at least one ring of the first barrier wall is disposed on each ring of the second barrier wall.

Further, the first barrier layer includes a first ring of second barrier wall and a second ring of second barrier wall arranged at interval on the non-display area, the first ring of second barrier wall is disposed around the edge of the display area, the second ring of second barrier wall is disposed around the first ring of second barrier wall, and a height of the second ring of second barrier wall is greater than a height of the first ring of second barrier wall.

Further, the display panel further including a metal layer, a first insulation layer, and a first pixel electrode sequentially disposed on the substrate, the metal layer, the first insulation layer, and the first pixel electrode lam inatedly disposed on the substrate to form a channel and a plurality of protrusions on two sides of the channel, wherein the first ring of second barrier wall is disposed in the channel, and the second ring of second wall is disposed on the protrusions.

Further, two rings of the first barrier walls are arranged at interval on the first ring of second barrier wall, and the two rings of the first barrier walls are arranged at interval on the second ring of second barrier wall.

Further, the display panel further including a metal layer, a first insulation layer, a first pixel electrode, a pixel definition layer, and a support pad sequentially disposed on the substrate, wherein the first barrier layer and the pixel definition layer are made of the same material and the same layer, the second barrier layer and the support pad are made of the same material and the same layer.

Further, a total width of at least two rings of the first barrier walls is less than a width of the first barrier layer.

Further, the display panel further including a thin film transistor array, a pixel, and a thin film encapsulation structure sequentially disposed on the display area of the substrate, wherein the thin film encapsulation structure includes a first inorganic layer, an organic layer, and a second inorganic layer laminatedly disposed.

In order to solve the above problems, an embodiment of the present application further provides a method of manufacturing a display panel, the method of manufacturing a display panel including: providing a substrate including a display area and a non-display area disposed around the display area; forming a first barrier layer disposed on the non-display area and around an edge of the display area; and forming a second barrier layer disposed on the first barrier layer; wherein the second barrier layer includes at least two rings of first barrier walls, and the first barrier walls are disposed around the display area.

Further, forming the first barrier layer disposed on the non-display area and around the edge of the display area specifically includes: forming a metal layer, a first insulation layer, and a first pixel electrode on the substrate sequentially; and forming a second insulating layer on the first pixel electrode and the first insulation layer not covered by the first pixel electrode, dividing the second insulating layer into a plurality of blocks by exposing and etching the second insulating layer to obtain a pixel definition layer in the display area, and obtaining the first barrier layer in the non-display area; wherein forming the second barrier layer disposed on the first barrier layer includes: forming a third insulation layer on the first barrier layer, dividing the third insulation layer into a plurality of blocks by exposing and etching the third insulation layer to obtain a support pad in the display area, and obtaining the second barrier layer in the non-display area.

Further, the first barrier layer includes at least one ring of second barrier wall, the second barrier wall is disposed around the edge of the display area, and at least one ring of the first barrier wall is disposed on each ring of the second barrier wall.

Further, the first barrier layer includes a first ring of second barrier wall and a second ring of second barrier wall arranged at interval on the non-display area, the first ring of second barrier wall is disposed around the edge of the display area, the second ring of second barrier wall is disposed around the first ring of second barrier wall, and a height of the second ring of second barrier wall is greater than a height of the first ring of second barrier wall.

Further, two rings of the first barrier walls are arranged at interval on the first ring of second barrier wall, and the two rings of the first barrier walls are arranged at interval on the second ring of second barrier wall.

In order to solve the above problems, an embodiment of the present application provides a display device, and the display device includes a driving circuitry and a display panel, and the driving circuitry configured to provide a driving voltage to the display panel, wherein the display panel includes: a substrate, the substrate including a display area and a non-display area disposed around the display area; a first barrier layer, disposed on the non-display area and disposed around an edge of the display area; a second barrier layer, disposed on the first barrier layer; wherein the second barrier layer includes at least two rings of first barrier walls, and the first barrier walls are disposed around the display area.

Further, the first barrier layer includes at least one ring of second barrier wall, the second barrier wall is disposed around the edge of the display area, and at least one ring of the first barrier wall is disposed on each ring of the second barrier wall.

Further, the first barrier layer includes a first ring of second barrier wall and a second ring of second barrier wall arranged at interval on the non-display area, the first ring of second barrier wall is disposed around the edge of the display area, the second ring of second barrier wall is disposed around the first ring of second barrier wall, and a height of the second ring of second barrier wall is greater than a height of the first ring of second barrier wall.

Further, the display panel further including a metal layer, a first insulation layer, and a first pixel electrode sequentially disposed on the substrate, the metal layer, the first insulation layer, and the first pixel electrode lam inatedly disposed on the substrate to form a channel and a plurality of protrusions on two sides of the channel, wherein the first ring of second barrier wall is disposed in the channel, and the second ring of second wall is disposed on the protrusions.

Further, two rings of the first barrier walls is arranged at interval on the first ring of second barrier wall, and the two rings of the first barrier walls are arranged at interval on the second ring of second barrier wall.

Further, the display panel further including a metal layer, a first insulation layer, a first pixel electrode, a pixel definition layer, and a support pad sequentially disposed on the substrate, wherein the first barrier layer and the pixel definition layer are made of the same material and the same layer, the second barrier layer and the support pad are made of the same material and the same layer.

Further, a total width of at least two rings of the first barrier walls is less than a width of the first barrier layer.

The beneficial effects of the application are as follows. Different from the current technology, the display panel provided by the present application includes a substrate, and the substrate includes a display area and a non-display area around the display area. The display panel further includes a first barrier layer disposed on the non-display area and disposed around an edge of the display area, and a second barrier layer disposed on the first barrier layer, wherein the second barrier layer includes at least two rings of first barrier walls, and the first barrier walls are disposed around the display area. In this way, the height of the barrier layer can be increased, and the number of barrier walls can be increased at the same time, thereby more effectively blocking the leakage of the thin film encapsulation material and protecting the organic material in the display area from water and oxygen, thereby improving stability and extending lifetime.

### BRIEF DESCRIPTION OF DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic structural top view of a display panel according to an embodiment of the present application.

FIG. 2 is a schematic cross-sectional view taken along line O-O′ of FIG. 1.

FIG. 3 is another schematic structural view of a display panel according to an embodiment of the present application.

FIG. 4 is a schematic cross-sectional view taken along line O-O′ of FIG. 3.

FIG. 5 is another structural diagram of a display panel according to an embodiment of the present application.

FIG. 6 is a schematic flowchart of a method for manufacturing a display panel according to an embodiment of the present application.

FIG. 7 is still another schematic flowchart of a method for manufacturing a display panel according to an embodiment of the present application.

FIG. 8 is a schematic structural diagram of a display device according to an embodiment of the present application.

### DETAILED DESCRIPTION OF EMBODIMENTS

The following content combines with the drawings and the embodiment for describing the present invention in detail. It is obvious that the following embodiments are only some embodiments of the present invention. For the skilled persons of ordinary skill in the art without creative effort, the other embodiments obtained thereby are still covered by the present invention.

In order to further improve the lifetime and stability of the device, the present application provides a display panel to optimize the structure of the barrier layer around the edge of the display area, the height of the barrier layer can be increased, and the number of barrier walls can be increased at the same time, thereby more effectively blocking the leakage of the thin film encapsulation material and protecting the organic material in the display area from water and oxygen, which is beneficial to improve stability and extend lifetime.

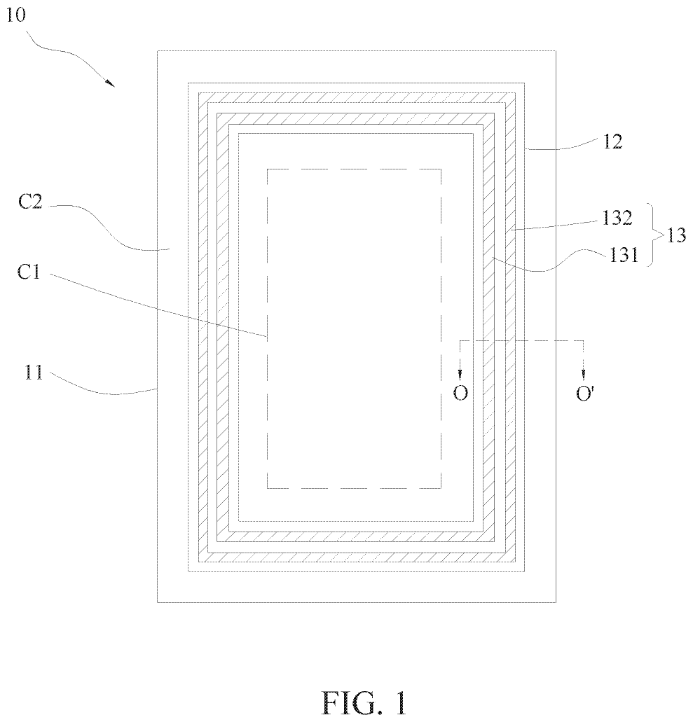

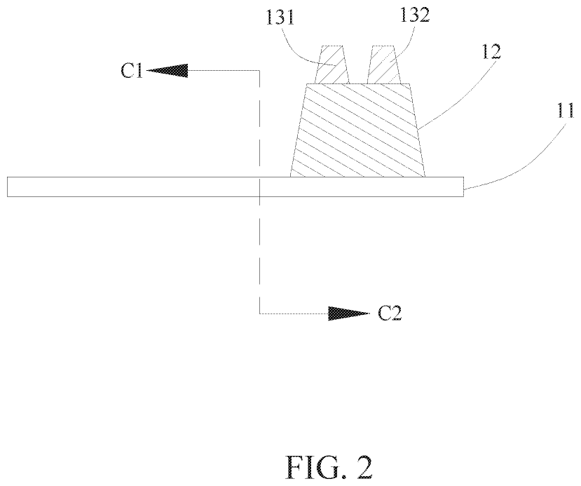

Referring to FIG. 1 and FIG. 2, FIG. 1 is a schematic structural top view of a display panel according to an embodiment of the present application, and FIG. 2 is a cross-sectional structural view taken along line O-O′ of FIG. 1. The display panel 10 includes a substrate 11, the substrate 11 includes a display area C1 and a non-display area C2 disposed around the display area C1. The display panel 10 further includes a first barrier layer 12 disposed on the non-display area C2 and disposed around the edge of the display area C1, and a second barrier layer 13 disposed on the first barrier layer 12. In this embodiment, the second barrier layer 13 includes at least two rings of first barrier walls 131/132, and the first barrier walls 131/132 are disposed around the display area C1.

Different from the current technology, the display panel provided by the present application through a setting of the second barrier layer on the first barrier layer, and the second barrier layer includes at least two rings of first barrier walls around the display area on the substrate, the height of the barrier layer can be increased and the number of barrier walls is increased at the same time, whereby further effectively blocks leakage of the thin film encapsulation material and protects the organic material in the display area from water and oxygen, which is beneficial to improve stability and extend lifetime.

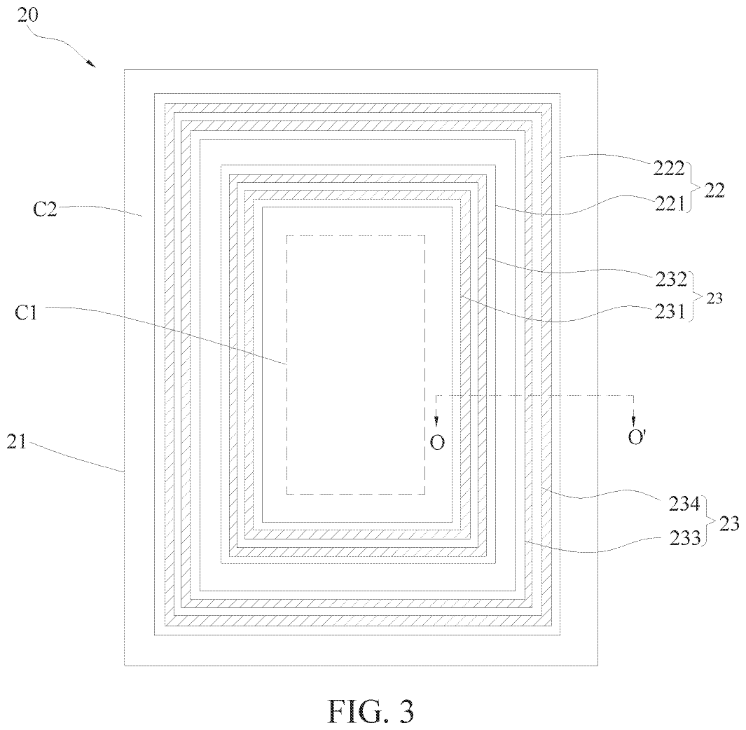

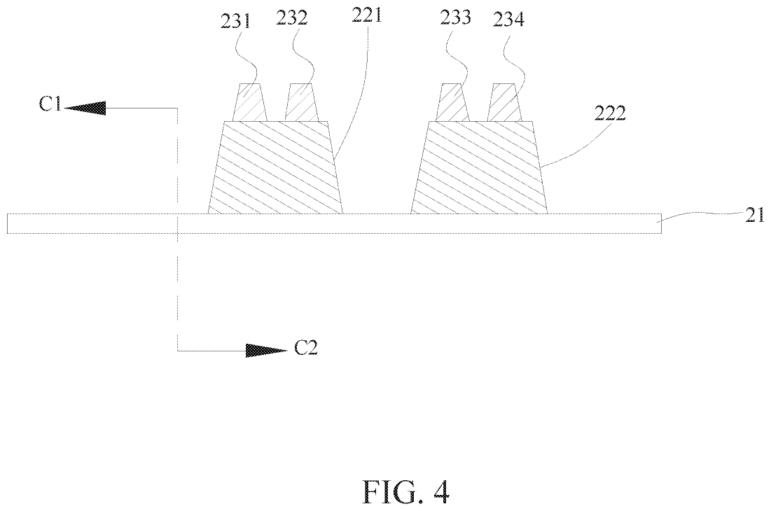

Referring to FIG. 3 and FIG. 4, FIG. 3 is another schematic structural view of the display panel according to an embodiment of the present application, and FIG. 4 is a cross-sectional structural view taken along line O-O′ of FIG. 3. A display panel 20 includes a substrate 21, and the substrate 21 includes a display area C1 and a non-display area C2 disposed around the display area C1. The display panel 20 further includes a first barrier layer 22 disposed on the non-display area C2 and disposed around the edge of the display area C1, and a second barrier layer 23 disposed on the first barrier layer 22. The second barrier layer 23 includes at least two rings of first barrier walls 231/232/233/234, and the barrier walls 231/232/233/234 are disposed around the display area C1.

In this embodiment, the substrate 21 can be a glass substrate or a hard resin substrate, or can be a flexible substrate for preparing a flexible display panel. The first barrier layer 22 and the second barrier layer 23 can be made of an organic insulation material such as polyimide or epoxy resin, or can be an inorganic insulation material such as SiNx or SiOx.

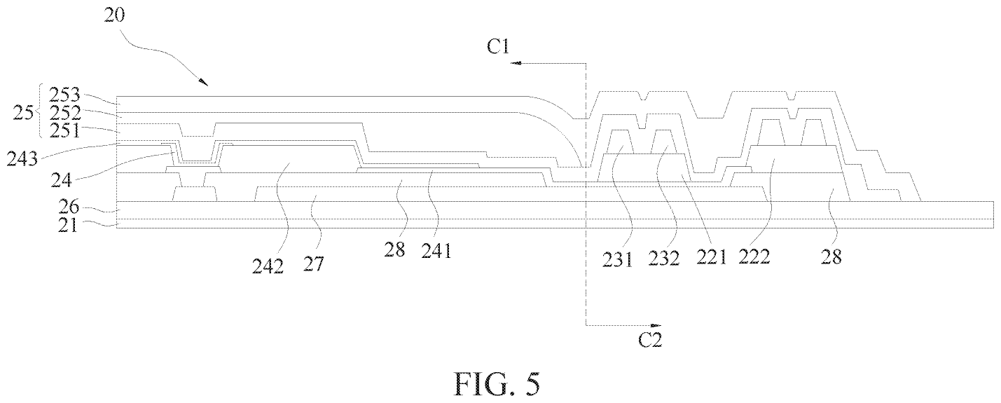

Specifically, referring to FIG. 5, the display panel 20 further includes a thin film transistor array (not shown), a pixel 24, and a thin film encapsulation structure 25 which are sequentially disposed on the display area C1 of the substrate 21. The thin film encapsulation structure 25 includes a first inorganic layer 251, an organic layer 252, and a second inorganic layer 253 which are laminatedly disposed. The organic layer 252 was prepared using an inkjet printing apparatus. The first barrier layer 22 and the second barrier layer 23 are disposed on the substrate 21 corresponding to a position of an inkjet printing boundary, and are used to define a boundary of the organic layer 252, so as to avoid the problem that the organic layer 252 cannot be shaped and flowed everywhere to cause leakage. The first barrier layer 22 and the second barrier layer 23 also block water oxygen to protect the organic material in the display area from water and oxygen.

The first inorganic layer 251 covers the display area C1 and is in contact with at least a portion of the first and second barrier layers 22/23. The organic layer 252 covers the display area C1 and its edge does not exceed an edge of the first inorganic layer 251. The second inorganic layer 253 covers the first and the second barrier layers 22/23 and the organic layer 252, and has an edge beyond an edge of the organic layer 252 for blocking external water oxygen from entering the display area C1.

Further, the first barrier layer 22 includes at least one ring of second barrier wall, the second barrier wall is disposed around the edge of the display area C1, and the plurality of second barrier walls are arranged at interval on the substrate 21, and the different second barrier walls have different blocking areas. For example, as shown in FIG. 4, the first barrier layer 22 includes two ring of second barrier walls, respectively a first ring of second barrier walls 221 and a second ring of second barrier walls 222, the second ring of second barrier walls 222 is disposed around the first ring of second barrier walls 221, and a projection of the area blocked by the first ring of second barrier walls 221 on the substrate 21 covers the display area C1, and a projection of the area blocked by the second ring of second barrier walls 222 on the substrate 21 covers the interval between the first ring of second barrier walls 221 and the second ring of second barrier walls 222. Similarly, the first barrier layer 22 can further includes a third ring of second barrier walls (not shown), the third ring of second barrier wall is disposed around the second ring of second barrier walls 222, and a projection of the area blocked by the third ring of second barrier walls on the substrate 21 covers the interval between the second ring of second barrier walls 222 and the third ring of second barrier walls, and so on.

The more the second barrier walls included in the first barrier layer 22, the better the blocking effect on the thin film encapsulation material and the water oxygen, however, the more the number of the second barrier wall means that the greater the width of the display panel border corresponding to non-display, it is not conducive to improve the screen ratio of the display panel.

In this embodiment, at least one ring of first barrier walls is disposed on each ring of the second barrier walls. For example, at least two rings of first barrier walls are disposed on each ring of the second barrier walls, so that a ring of the second barrier wall can achieve a multi-channel blocking effect.

For example, referring to FIG. 3 and FIG. 4, the first barrier layer 22 includes a first ring of second barrier wall 221 and a second ring of second barrier wall 222, and the second barrier layer 23 includes a first ring of first barrier wall 231 and a second ring of first barrier wall 232 disposed on the first ring of second barrier wall 221, and a third ring of first barrier wall 233 and a fourth ring of first barrier wall 234 are disposed on the second ring of second barrier wall 222. Thus, by disposing the second barrier layer 23 on the first barrier layer 22, the two barriers of the original first barrier layer 22 are increased to four barriers after the second barrier layer 23 is set, and the width of the barrier layer is unchanged. At the same time, the height of the barrier layer is increased, which can more effectively block the leakage of the thin film encapsulation material and prevent the organic material in the display area from being eroded by water and oxygen.

In some embodiments, in order to pursue a high screen ratio of the display panel, the first barrier layer 22 includes only one ring of second barrier wall, and the second barrier layer 23 is disposed on the second barrier wall. The second barrier layer 23 includes at least two rings of first barrier walls. As such, although the number of the second barrier walls included in the first barrier layer 22 is reduced, by disposing the second barrier layer 23 on the first barrier layer 22, the second barrier layer 23 includes at least two rings of first barrier walls. It can also achieve multi-channel blocking effect.

Wherein, when a plurality of rings of the first barrier walls are disposed on one of the second barrier walls of the first barrier layer 22, the plurality of rings of the first barrier walls can be disposed interval on the second barrier walls and have the same interval width.

In a specific embodiment, a total width of the at least two rings of the first barrier walls included in the second barrier layer 23 is not greater than a width of the first barrier layer 22, that is, by disposing the second barrier layer 23 on the first barrier layer 22 which only increases the height of the barrier layer and does not increase the width of the barrier layer.

Continuing to refer to FIG. 5, the present embodiment will be described in detail below in the light of the specific structure of the display panel. The display panel 20 includes a substrate 21, and a buffer layer 26, a metal layer 27, a first insulation layer 28, a first pixel electrode 241, a pixel definition layer 242, a support pad (not shown), a pixel 24, a second pixel electrode 243, first inorganic layer 251, organic layer 252, and second inorganic layer 253, which are sequentially disposed on the substrate 21. The first barrier layer 22 is disposed in the same layer as the pixel definition layer 242 and the material is the same, and the second barrier layer 23 is disposed in the same layer as the support pad and the material is the same. That is, the first barrier layer 22 and the pixel definition layer 242 can be formed by one patterning process, and the second barrier layer 23 and the support pad can be formed by one patterning process.

In this embodiment, the first pixel electrode 241 is a pixel anode electrode layer, the second pixel electrode 243 is a pixel cathode electrode layer, and the pixel definition layer 242 and the support pad can be inorganic insulating materials such as SiNx and SiOx.

In one embodiment, the first barrier layer 22 includes a first ring of second barrier wall 221 and a second ring of second barrier wall 222 around the first ring of second barrier wall 221. The height of the second ring of second barrier wall 222 relative to the substrate 21 is greater than the height of the first ring of second barrier wall 221 relative to the substrate 21. Specifically, the metal layer 27, the first insulation layer 28, and the first pixel electrode 241 are patterned layer structures. After the buffer layer 26, the metal layer 27, the first insulation layer 28, and the first pixel electrode 241 are sequentially disposed on the substrate 21, the metal layer 27, the first insulation layer 28, and the first pixel electrode 241 are laminatedly disposed on the substrate 21 to form a channel and a plurality of protrusions on two sides of the channel. Wherein the first ring of second barrier wall 221 is disposed in the channel, and the second ring of second barrier wall 222 is disposed on the protrusions. Therefore, the height of the second ring of second barrier wall 222 is greater than the height of the first ring of second barrier wall 221, as such, it is advantageous for the second ring of second barrier wall 222 to buffer and further block the thin film encapsulation material that overflows the first ring of second barrier wall 221.

Different from the current technology, the display panel provided by the present application through a setting of the second barrier layer on the first barrier layer, and the second barrier layer includes at least two rings of first barrier walls around the display area on the substrate, the height of the barrier layer can be increased and the number of barrier walls is increased at the same time, whereby further effectively blocks the leakage of the thin film encapsulation material and protects the organic material in the display area from water and oxygen, which is beneficial to improve stability and extend lifetime.

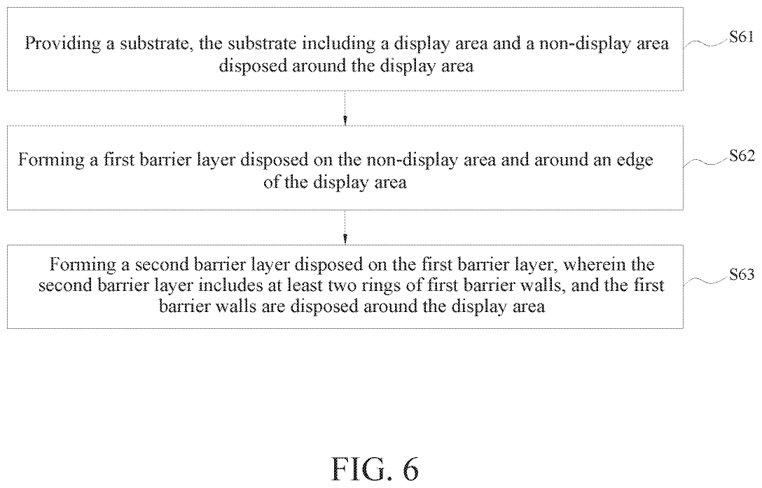

Please refer to FIG. 6, FIG. 6 is a schematic flowchart of a method of manufacturing a display panel according to an embodiment of the present application. The manufacturing method of the display panel includes the following steps:

S61: providing a substrate, the substrate including a display area and a non-display area disposed around the display area.

In this embodiment, the substrate can be a glass substrate or a hard resin substrate, or can be a flexible substrate for preparing a flexible display panel.

S62: forming a first barrier layer disposed on the non-display area and around an edge of the display area.

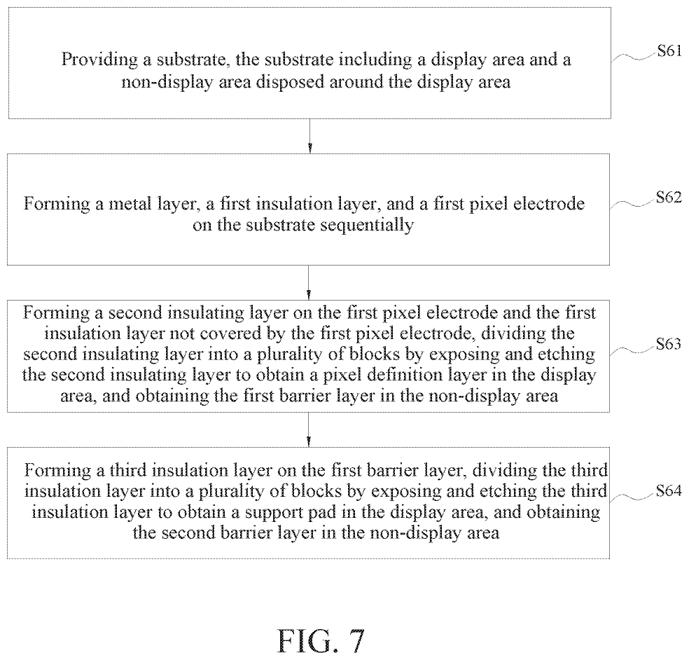

Referring to FIG. 7, this step specifically includes the following sub-steps:

S621: forming a metal layer, a first insulation layer, and a first pixel electrode on the substrate sequentially;

S622: forming a second insulating layer on the first pixel electrode and the first insulation layer not covered by the first pixel electrode, dividing the second insulating layer into a plurality of blocks by exposing and etching the second insulating layer to obtain a pixel definition layer in the display area, and obtaining the first barrier layer in the non-display area.

The first barrier layer includes at least one ring of second barrier wall, the second barrier wall is disposed on the non-display area and around the edge of the display area. The plurality of rings of the second barrier walls are formed interval on the substrate, and different second barrier walls have different blocking areas. For example, the first barrier layer includes two rings of second barrier walls, respectively, a first ring of second barrier wall and a second ring of second barrier wall. The second ring of second barrier wall is disposed around the first ring of second barrier wall. A projection of the area blocked by the first ring of second barrier wall on the substrate covers the display area, and a projection of the area blocked by the second ring of second barrier wall on the substrate covers the interval between the first ring of second barrier wall and second ring of second barrier wall. Similarly, the first barrier layer can further includes a third ring of second barrier walls, the third ring of second barrier wall is disposed around the second ring of second barrier walls, and a projection of the area blocked by the third ring of second barrier walls on the substrate covers the interval between the second ring of second barrier walls and the third ring of second barrier walls, and so on.

S63: forming a second barrier layer disposed on the first barrier layer, wherein the second barrier layer includes at least two rings of first barrier walls, and the first barrier walls are disposed around the display area.

This step specifically can include:

S631: forming a third insulation layer on the first barrier layer, dividing the third insulation layer into a plurality of blocks by exposing and etching the third insulation layer to obtain a support pad in the display area, and obtaining the second barrier layer in the non-display area.

In this embodiment, at least one ring of first barrier walls is disposed on each ring of the second barrier walls of the first barrier layer. For example, at least two rings of first barrier walls are disposed on each ring of the second barrier walls, so that a ring of the second barrier wall can achieve a multi-channel blocking effect.

Wherein, when a plurality of rings of the first barrier walls are disposed on one of the second barrier walls of the first barrier layer, the plurality of rings of the first barrier walls can be disposed interval on the second barrier walls and have the same interval width.

In a specific embodiment, a total width of the at least two rings of the first barrier walls included in the second barrier layer is not greater than a width of the first barrier layer, that is, by disposing the second barrier layer on the first barrier layer which only increases the height of the barrier layer and does not increase the width of the barrier layer.

In the above embodiment, the method of manufacturing the display panel further includes sequentially forming a thin film transistor, a pixel, and a thin film encapsulation structure on the display area of the substrate. The thin film encapsulation structure includes a first inorganic layer, an organic layer, and a second inorganic layer which are laminatedly disposed, and the organic layer is prepared by an inkjet printing apparatus. Wherein, the first barrier layer and the second barrier layer are disposed on the substrate corresponding to a position of an inkjet printing boundary, and are used to define a boundary of the organic layer, so as to avoid the problem that the organic layer cannot be shaped and flowed everywhere to cause leakage. The first barrier layer and the second barrier layer also block water oxygen to protect the organic material in the display area from water and oxygen.

Specifically, the first inorganic layer covers the display area and is in contact with at least a portion of the first and second barrier layers. The organic layer covers the display area and its edge does not exceed an edge of the first inorganic layer. The second inorganic layer covers the first and the second barrier layers and the organic layer, and has an edge beyond an edge of the organic layer for blocking external water oxygen from entering the display area.

For example, the method of manufacturing the display panel according to an embodiment of the present application can be specifically implemented as the following steps:

S101, growing a SiNx/SiOx buffer layer on the substrate by a chemical vapor deposition process;

S102, depositing a metal layer by a physical vapor deposition process; patterning the metal layer by an exposure and etching process;

S103, forming the first insulation layer by a coating process, and patterning the first insulation layer by an exposure and development process;

S104, forming a pixel anode electrode by a physical vapor deposition process, and dividing the pixel anode electrode into a plurality of blocks by an exposure and etching process;

S105, forming a second insulating layer by using a chemical vapor deposition process, forming a pixel definition layer in the display area by using an exposure and etching process, and forming a first barrier layer around the edge of the display area in the non-display area;

S106, using a chemical vapor deposition process to form a third insulation layer, forming a support pad in the display area by using an exposure and etching process, and forming a second barrier layer around the display area in the non-display area;

S107, forming a first inorganic layer by an atomic layer deposition or a chemical vapor deposition process, such that the first inorganic layer covers the display area and at least a portion of the first barrier layer and the second barrier layer;

S108, forming an organic layer by inkjet printing, the organic layer covering the display area and having an edge not exceeding an edge of the first inorganic layer;

S109, forming a second inorganic layer by chemical vapor deposition, the second inorganic layer covering the organic layer, and a coverage area of the second inorganic layer is the same as the first inorganic layer.

Different from the current technology, the manufacturing method of the display panel in this embodiment through a setting of the second barrier layer on the first barrier layer, and the second barrier layer includes at least two rings of first barrier walls around the display area on the substrate, the height of the barrier layer can be increased and the number of barrier walls is increased at the same time, whereby further effectively blocks the leakage of the thin film encapsulation material and protects the organic material in the display area from water and oxygen, which is beneficial to improve stability and extend lifetime.

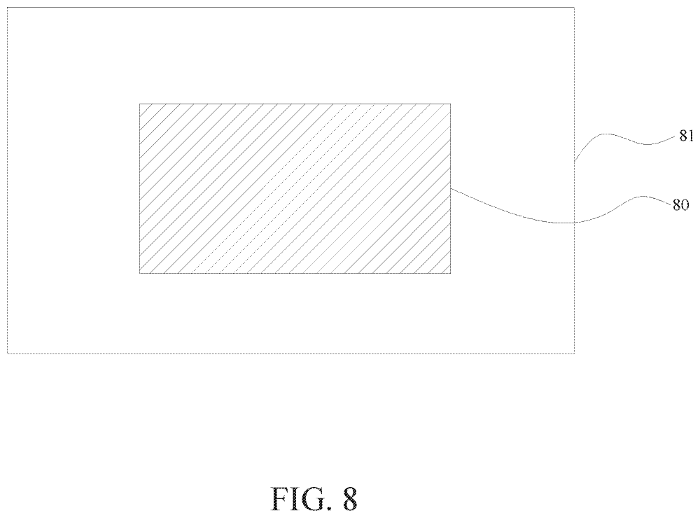

Referring to FIG. 8, an embodiment of the present application further provides a display device, the display device 80 includes a driving circuitry and any of the above display panels 81, wherein the driving circuitry is configured to provide a driving voltage to the display panel 81.

The display panel 81 includes a substrate, the substrate includes a display area and a non-display area disposed around the display area. The display panel further includes a first barrier layer disposed on the non-display area and disposed around an edge of the display area, and a second barrier layer disposed on the first barrier layer. Wherein the second barrier layer includes at least two rings of first barrier walls, and the first barrier walls are disposed around the display area.

Different from the current technology, the display device in this embodiment through a setting of the second barrier layer on the first barrier layer, and the second barrier layer includes at least two rings of first barrier walls around the display area on the substrate, the height of the barrier layer can be increased and the number of barrier walls is increased at the same time, whereby further effectively blocks the leakage of the thin film encapsulation material and protects the organic material in the display area from water and oxygen, which is beneficial to improve stability and extend lifetime.

The technical scope of the present invention is not limited to the above description, a person skilled in the art can make various modifications and changes to the above embodiments without departing from the technical idea of the present invention, and such variations and modifications are intended to be within the scope of the invention.

What is claimed is:

1. A display panel, comprising:
a substrate comprising a display area and a non-display area disposed around the display area;
a first barrier layer disposed on the non-display area and disposed around an edge of the display area; and
a second barrier layer disposed on the first barrier layer;
wherein the second barrier layer comprises at least two rings of first barrier walls, and the first barrier walls are disposed around the display area.

2. The display panel according to claim 1, wherein the first barrier layer comprises at least one ring of second barrier wall, the second barrier wall is disposed around the edge of the display area, and at least one ring of the first barrier wall is disposed on each ring of the second barrier walls.

3. The display panel according to claim 2, wherein the first barrier layer comprises a first ring of second barrier wall and a second ring of second barrier wall arranged at interval on the non-display area, the first ring of second barrier wall is disposed around the edge of the display area, the second ring of second barrier wall is disposed around the first ring of second barrier wall, and a height of the second ring of second barrier wall is greater than a height of the first ring of second barrier wall.

4. The display panel according to claim 3, further comprising a metal layer, a first insulation layer, and a first pixel electrode sequentially disposed on the substrate, the metal layer, the first insulation layer, and the first pixel electrode laminatedly disposed on the substrate to form a channel and a plurality of protrusions on two sides of the channel, wherein the first ring of second barrier wall is disposed in the channel, and the second ring of second wall is disposed on the protrusions.

5. The display panel according to claim 3, wherein two rings of the first barrier walls are arranged at interval on the first ring of second barrier wall, and the two rings of the first barrier walls are arranged at interval on the second ring of second barrier wall.

6. The display panel according to claim 1, further comprising a metal layer, a first insulation layer, a first pixel electrode, a pixel definition layer, and a support pad sequentially disposed on the substrate, wherein the first barrier layer and the pixel definition layer are made of the same material and the same layer, the second barrier layer and the support pad are made of the same material and the same layer.

7. The display panel according to claim 1, wherein a total width of at least two rings of the first barrier walls is less than a width of the first barrier layer.

8. The display panel according to claim 1, further comprising a thin film transistor array, a pixel, and a thin film encapsulation structure sequentially disposed on the display area of the substrate, wherein the thin film encapsulation structure comprises a first inorganic layer, an organic layer, and a second inorganic layer laminatedly disposed.

9. A method of manufacturing a display panel, comprising:
providing a substrate comprising a display area and a non-display area disposed around the display area;
forming a first barrier layer disposed on the non-display area and around an edge of the display area; and
forming a second barrier layer disposed on the first barrier layer;
wherein the second barrier layer comprises at least two rings of first barrier walls, and the first barrier walls are disposed around the display area.

10. The method of manufacturing a display panel according to claim 9, wherein forming the first barrier layer disposed on the non-display area and around the edge of the display area comprises:
forming a metal layer, a first insulation layer, and a first pixel electrode on the substrate sequentially; and
forming a second insulating layer on the first pixel electrode and the first insulation layer not covered by the first pixel electrode, dividing the second insulating layer into a plurality of blocks by exposing and etching the second insulating layer to obtain a pixel definition layer in the display area, and obtaining the first barrier layer in the non-display area;
wherein forming the second barrier layer disposed on the first barrier layer comprises:
forming a third insulation layer on the first barrier layer, dividing the third insulation layer into a plurality of blocks by exposing and etching the third insulation layer to obtain a support pad in the display area, and obtaining the second barrier layer in the non-display area.

11. The method of manufacturing a display panel according to claim 9, wherein the first barrier layer comprises at least one ring of second barrier wall, the second barrier wall is disposed around the edge of the display area, and at least one ring of the first barrier wall is disposed on each ring of the second barrier wall.

12. The method of manufacturing a display panel according to claim 11, wherein the first barrier layer comprises a first ring of second barrier wall and a second ring of second barrier wall arranged at interval on the non-display area, the first ring of second barrier wall is disposed around the edge of the display area, the second ring of second barrier wall is disposed around the first ring of second barrier wall, and a height of the second ring of second barrier wall is greater than a height of the first ring of second barrier wall.

13. The method of manufacturing a display panel according to claim 12, wherein two rings of the first barrier walls are arranged at interval on the first ring of second barrier wall, and the two rings of the first barrier walls are arranged at interval on the second ring of second barrier wall.

14. A display device comprising a driving circuitry and a display panel, and the driving circuitry configured to provide a driving voltage to the display panel, wherein the display panel comprises:
a substrate, the substrate comprising a display area and a non-display area disposed around the display area;
a first barrier layer, disposed on the non-display area and disposed around an edge of the display area;
a second barrier layer, disposed on the first barrier layer;
wherein the second barrier layer comprises at least two rings of first barrier walls, and the first barrier walls are disposed around the display area.

15. The display device according to claim 14, wherein the first barrier layer comprises at least one ring of second barrier wall, the second barrier wall is disposed around the edge of the display area, and at least one ring of the first barrier wall is disposed on each ring of the second barrier wall.

16. The display device according to claim 15, wherein the first barrier layer comprises a first ring of second barrier wall and a second ring of second barrier wall arranged at interval on the non-display area, the first ring of second barrier wall is disposed around the edge of the display area, the second ring of second barrier wall is disposed around the first ring of second barrier wall, and a height of the second ring of second barrier wall is greater than a height of the first ring of second barrier wall.

17. The display device according to claim 16, further comprising a metal layer, a first insulation layer, and a first pixel electrode sequentially disposed on the substrate, the metal layer, the first insulation layer, and the first pixel electrode laminatedly disposed on the substrate to form a channel and a plurality of protrusions on two sides of the channel, wherein the first ring of second barrier wall is disposed in the channel, and the second ring of second wall is disposed on the protrusions.

18. The display device according to claim 16, wherein two rings of the first barrier walls is arranged at interval on the first ring of second barrier wall, and the two rings of the first barrier walls are arranged at interval on the second ring of second barrier wall.

19. The display device according to claim 14, further comprising a metal layer, a first insulation layer, a first pixel electrode, a pixel definition layer, and a support pad sequentially disposed on the substrate, wherein the first barrier layer and the pixel definition layer are made of the same material and the same layer, the second barrier layer and the support pad are made of the same material and the same layer.

20. The display device according to claim 14, wherein a total width of at least two rings of the first barrier walls is less than a width of the first barrier layer.
